(19) United States
(12) Patent Application Publication
(10) Pub. No.: US 2020/0358538 A1
(43) Pub. Date: Nov. 12, 2020

(54) System and Method For Testing A Wireless Data Packet Signal Transceiver

(71) Applicant: LitePoint Corporation, Sunnyvale, CA (US)

(72) Inventors: Christian Volf Olgaard, Saratoga, CA (US); Brad Robbins, Mountain View, CA (US); Yen-Fang Chao, Pleasanton, CA (US)

(21) Appl. No.: 16/407,923

(22) Filed: May 9, 2019

(51) Int. Cl. H04B 17/16; H04B 17/29; H04B 17/10; H04B 17/00; G01R 29/08

(52) U.S. Cl. CPC H04B 17/16; H04B 17/29; G01R 29/0821; H04B 17/0087; H04B 17/0085; H04B 17/103

(57) ABSTRACT

System and method for testing a wireless signal transceiver device under test (DUT) via a wireless signal path using one or more electromagnetic lenses to provide one or more focused electromagnetic test signals to a quiet zone region enveloping at least a portion of the DUT.

### BACKGROUND

The present invention relates to testing a data packet signal transceiver device under test (DUT), and in particular, over-the-air (OTA) testing of wireless transmission and/or reception performance of a wireless radio frequency (RF) DUT using focused electromagnetic test signals.

Many of today's electronic devices use wireless signal technologies for both connectivity and communications purposes. Because wireless devices transmit and receive electromagnetic energy, and because two or more wireless devices have the potential of interfering with the operations of one another by virtue of their signal frequencies and power spectral densities, these devices and their wireless signal technologies must adhere to various wireless signal technology standard specifications.

When designing such wireless devices, engineers take extra care to ensure that such devices will meet or exceed each of their included wireless signal technology prescribed standard-based specifications. Furthermore, when these devices are later being manufactured in quantity, they are tested to ensure that manufacturing defects will not cause improper operation, including their adherence to the included wireless signal technology standard-based specifications.

Testing of such wireless devices typically involves testing of the receiving and transmitting subsystems of the device under test (DUT). The testing system will send a prescribed sequence of test data packet signals to a DUT, e.g., using different frequencies, power levels, and/or signal modulation techniques to determine if the DUT receiving subsystem is operating properly. Similarly, the DUT will send test data packet signals at a variety of frequencies, power levels, and/or modulation techniques for reception and processing by the testing system to determine if the DUT transmitting subsystem is operating properly.

For testing these devices following their manufacture and assembly, current wireless device test systems typically employ testing systems having various subsystems for providing test signals to each device under test (DUT) and analyzing signals received from each DUT. Some systems (often referred to as “testers”) include, at least, one or more sources of test signals (e.g., in the form of a vector signal generator, or “VSG”) for providing the source signals to be transmitted to the DUT, and one or more receivers (e.g., in the form of a vector signal analyzer, or “VSA”) for analyzing signals produced by the DUT. The production of test signals by the VSG and signal analysis performed by the VSA are generally programmable (e.g., through use of an internal programmable controller or an external programmable controller such as a personal computer) so as to allow each to be used for testing a variety of devices for adherence to a variety of wireless signal technology standards with differing frequency ranges, bandwidths and signal modulation characteristics.

As mobile wireless communication devices have become more widely used for many purposes, availability of sufficient signal bandwidth to accommodate the many varied uses (e.g., streaming of video and/or more uses of video in two-way communications in particular), has become a critical issue. This has led to more use of higher signal frequencies, such as extremely high frequency (EHF), which is the International Telecommunication Union (ITU) designation for radio frequencies in the electromagnetic spectrum band of 30-300 gigahertz (GHz), in which radio waves have wavelengths of 10-1 millimeter, and are often referred to as millimeter wave (mmW) signals. Performing over-the-air (OTA) testing of such systems is presenting unique challenges in minimizing test time while maintaining consistency of measurements.

### SUMMARY

A system and method are provided for testing a wireless signal transceiver device under test (DUT) via a wireless signal path using one or more electromagnetic lenses to provide one or more focused electromagnetic test signals to a quiet zone region enveloping at least a portion of the DUT.

In accordance with example embodiments, a system for testing a wireless signal transceiver device under test (DUT) via a wireless signal path includes: a tester antenna configured to emit an electromagnetic tester signal and to receive a focused electromagnetic DUT signal; a DUT location for disposition of a DUT to receive a focused electromagnetic tester signal and emit an electromagnetic DUT signal; and an electromagnetic lens disposed between the tester antenna and the DUT location to focus the electromagnetic tester signal to provide the focused electromagnetic tester signal within a volume that defines a quiet zone region enveloping at least a portion of the DUT location, and to focus the electromagnetic DUT signal to provide the focused electromagnetic DUT signal.

In accordance with further example embodiments, a method for testing a wireless signal transceiver device under test (DUT) via a wireless signal path includes: emitting an electromagnetic tester signal from a tester antenna; focusing, with an electromagnetic lens, the electromagnetic tester signal to provide a focused electromagnetic tester signal within a volume that defines a quiet zone region; and receiving the focused electromagnetic tester signal with a DUT disposed at least partially in the quiet zone region.

In accordance with further example embodiments, the method further includes emitting an electromagnetic DUT signal from the DUT; focusing, with the electromagnetic lens, the electromagnetic DUT signal to provide a focused electromagnetic DUT signal; and receiving, with the tester antenna, the focused electromagnetic DUT signal.

### BRIEF DESCRIPTION OF THE DRAWINGS

FIG. 1 depicts a wired, or conductive, test environment for testing a data packet signal transceiver device.

FIG. 2 depicts a wireless, or radiative, test environment for testing a data packet signal transceiver device in accordance with example embodiments.

FIG. 3 depicts an OTA test environment with a shielded enclosure for testing a data packet signal transceiver device in accordance with example embodiments.

FIG. 4 depicts path loss floors for near-field focus (NFF) and far-field focus (FFF) testing environments.

FIG. 5 depicts an example of a testing environment for enabling NFF and FFF testing.

FIG. 6 depicts an example of a testing environment for enabling indirect far field (IFF) testing.

FIG. 7 depicts a lens-based FFF testing environment in accordance with an example embodiment.

FIG. 8 depicts a lens-based NFF testing environment in accordance with an example embodiment.

FIG. 9 depicts examples of NFF quiet zone (QZ) characteristics.

FIG. 10 depicts field plots of example NFF QZ characteristics.

FIG. 11 depicts a lens-based testing environment for enabling NFF and/or FFF testing in accordance with example embodiments.

FIG. 12 depicts path loss compensation for NFF and FFF testing environments in accordance with example embodiments.

### DETAILED DESCRIPTION

The following detailed description is of example embodiments of the presently claimed invention with references to the accompanying drawings. Such description is intended to be illustrative and not limiting with respect to the scope of the present invention. Such embodiments are described in enough detail to enable one of ordinary skill in the art to practice the subject invention, and it will be understood that other embodiments may be practiced with some variations without departing from the spirit or scope of the subject invention.

Throughout the present disclosure, absent a clear indication to the contrary from the context, it will be understood that individual circuit elements as described may be singular or plural in number. For example, the terms “circuit” and “circuitry” may include either a single component or a plurality of components, which are either active and/or passive and are connected or otherwise coupled together (e.g., as one or more integrated circuit chips) to provide the described function. Additionally, the term “signal” may refer to one or more currents, one or more voltages, or a data signal. Within the drawings, like or related elements will have like or related alpha, numeric or alphanumeric designators. Further, while the present invention has been discussed in the context of implementations using discrete electronic circuitry (preferably in the form of one or more integrated circuit chips), the functions of any part of such circuitry may alternatively be implemented using one or more appropriately programmed processors, depending upon the signal frequencies or data rates to be processed. Moreover, to the extent that the figures illustrate diagrams of the functional blocks of various embodiments, the functional blocks are not necessarily indicative of the division between hardware circuitry.

Wireless devices, such as cellphones, smartphones, tablets, etc., make use of standards-based technologies, such as IEEE 802.11a/b/g/n/ac (“WiFi”), 3GPP LTE, Bluetooth, Zigbee, Z-Wave, etc. The standards that underlie these technologies are designed to provide reliable wireless connectivity and/or communications. The standards prescribe physical and higher-level specifications generally designed to be energy-efficient and to minimize interference among devices using the same or other technologies that are adjacent to or share the wireless spectrum.

Tests prescribed by these standards are meant to ensure that such devices are designed to conform to the standard-prescribed specifications, and that manufactured devices continue to conform to those prescribed specifications. Most devices are transceivers, containing at least one or more receivers and one or more transmitters. Thus, the tests are intended to confirm whether the receivers and transmitters both conform. Tests of the receiver(s) of the DUT (RX tests) typically involve a test system (tester) sending test packets to the receiver(s) and some way of determining how the DUT receiver(s) respond to those test packets. Tests of the transmitter(s) of the DUT (TX tests) are performed by having them send packets to the test system, which may then evaluate various physical characteristics of the signals from the DUT.

As discussed in more detail below, example embodiments advantageously improve link dynamic range of a mobile device OTA test environment without need for expensive mmWave hardware, while also providing path loss compensation without negatively affecting dynamic range of the tester, as well as enabling use of a common test chamber configuration for different DUT antenna array sizes with no path length adjustment required.

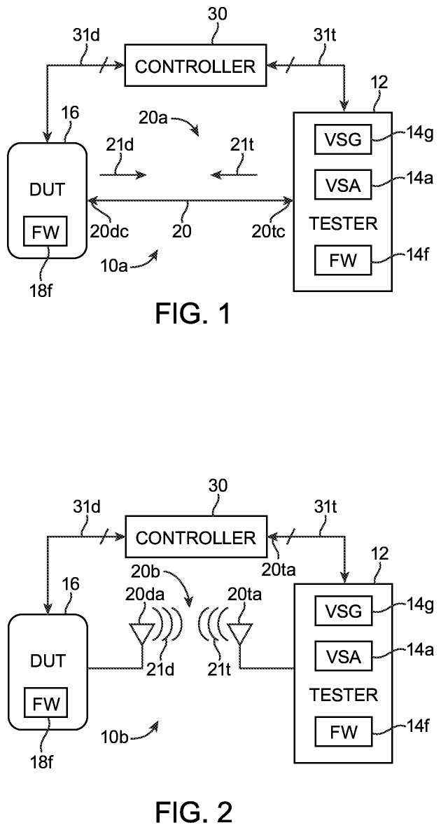

Referring to FIG. 1, a typical testing environment 10a includes a tester 12 and a DUT 16, with test data packet signals 21t and DUT data packet signals 21d exchanged as RF signals conveyed between the tester 12 and DUT 16 via a conductive signal path 20a, typically in the form of co-axial RF cable 20c and RF signal connectors 20tc, 20dc. As noted above, the tester typically includes a signal source 14g (e.g., a VSG) and a signal analyzer 14a (e.g., a VSA). The tester 12 and DUT 16 may also include preloaded information regarding predetermined test sequences, typically embodied in firmware 14f within the tester 12 and firmware 18f within the DUT 16. The testing details within this firmware 14f, 18f about the predetermined test flows typically require some form of explicit synchronization between the tester 12 and DUT 16, typically via the data packet signals 21t, 21d.

Alternatively, and in accordance with example embodiments, testing may be controlled by a controller 30 which may be integral to the tester 12 or external (e.g., a local or networked programmed personal computer) as depicted here. The controller 30 may communicate with the DUT 16 via one or more signal paths (e.g., Ethernet cabling, network switches and/or routers, etc.) 31d to convey commands and data. If external to the tester 12, the controller 30 may further communicate with the tester 12 via one or more additional signal paths (e.g., Ethernet cabling, network switches and/or routers, etc.) 31t to convey additional commands and data.

While the controller 30 and tester 12 are depicted as separate devices or systems, references to a “tester” in the following discussion may include separate devices or systems as depicted here and may also include a combined device or system in which the functions and capabilities of the controller 30 and tester 12 described above may be co-located in a common hardware infrastructure. Accordingly, unless otherwise specifically required or limited, references made to various control functions and/or commands may be considered to originate in a tester 12, a controller 30 or a combined tester/controller system (not shown). Similarly, storage of commands, data, etc., may be considered to be done in a tester 12, a controller 30 or a combined tester/controller system, or alternatively in memory devices located remotely via a network as noted above.

Referring to FIG. 2, an alternative testing environment 10b uses a wireless signal path 20b via which the test data packet signals 21t and DUT data packet signals 21d may be communicated via respective antenna systems 20ta, 20da of the tester 12 and DUT 16.

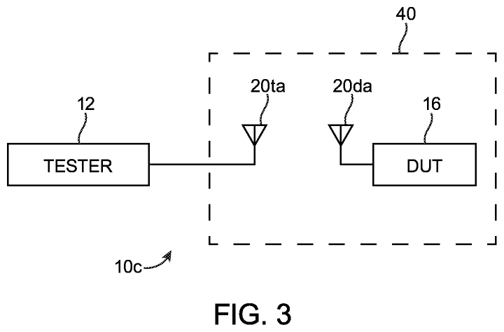

Referring to FIG. 3, an OTA test environment 10c for testing a DUT 16 in accordance with example embodiments includes a shielded enclosure 40. In accordance with well known electromagnetic signal transmission and shielding principles, such enclosures may be designed to be fabricated of appropriate materials (e.g., anechoic) having predetermined dimensions (e.g., having prescribed relationships and/or proportions based on signal wavelengths) appropriate for the signal frequencies of interest and/or concern (e.g., in terms of the signal frequencies of interest for transmission and reception by the tester 12 and DUT 16, as well as other potential interfering signal frequencies).

As noted above, the next generation of mmWave mobile devices often features highly integrated system architectures that include one or more antenna arrays. Evaluation of such a DUT is commonly done by an OTA test in an anechoic chamber in which DUT performance is evaluated in a quiet zone (QZ) in which an equal-phase plane wave is provided. Such a QZ maximizes measurement accuracy and repeatability of test results for the antenna array(s). As discussed in more detail below, common techniques to create the QZ condition are referred to as direct far field (DFF) and indirect far field (IFF).

In the DFF approach, QZ is restricted to the test range beyond the far field boundary of tester and DUT antennas. The far field boundary Rmin is defined as:

$${R}_{min} = \frac{2 {L}_{max}^{2}}{λ}$$

where Lₘₐₓ is the maximum aperture size of the antenna. The corresponding link transfer function from DUT to tester is given by:

$$\frac{{P}_{T e s t e r}}{{P}_{D U T}} = {G}_{T e s t e r} {{G}_{D U T} ( \frac{λ}{4 π {R}_{min}} )}^{2}$$

Where the path loss of the link is defined as:

$${( \frac{λ}{4 π {R}_{min}} )}^{2}$$

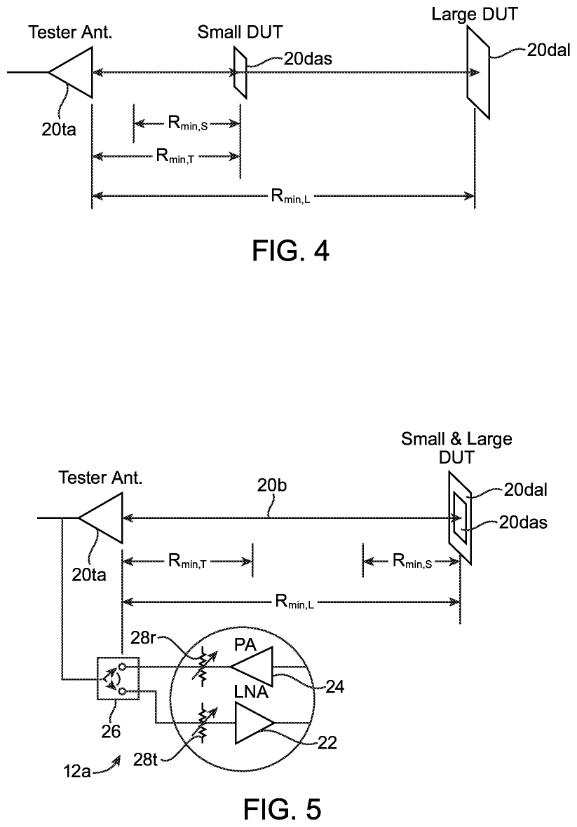

Referring to FIG. 4, minimum DFF distance Rₘᵢₙ often imposes a path loss floor to the link measurement and is likely dominated by the DUT for a large DUT antenna array 20dal and by the tester antenna 20ta for a small DUT antenna array 20das. Improving the path loss by increasing tester antenna gain has limited effect since it also increases the DFF distance and hence the path loss.

Referring to FIG. 5, using a common path length for all DUTs with different antenna array sizes may be more problematic. Typical Lₘₐₓ of mmWave mobile devices ranges from 1.5 to 5.0 cm. With a 5 cm aperture at 40 GHz, Rₘᵢₙ is 67 cm resulting in 61 dB of path loss. Improving the path loss by increase tester antenna gain has limited effect since it also increases the DFF distance and hence increases the path loss. Another approach is to use power amplifier PA 24 (e.g., in the VSG 14g) during DUT RX test and a low noise amplifier LNA 22 (e.g., in the VSA 14a) during DUT TX test (e.g., with transmit/receive switch circuitry 26, and variable attenuators 28t, 28r as additional integral components of the tester 12a). However, performance degradation by distortion may be introduced and significant cost added from such mmWave components generally make this approach less desirable.

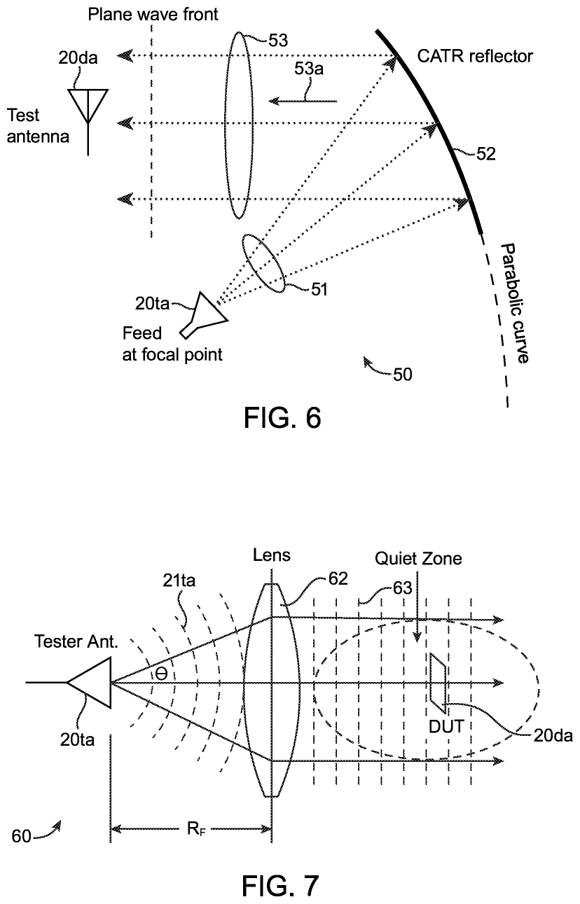

Referring to FIG. 6, an IFF testing environment 50 may overcome the DFF constraints of Rₘᵢₙ by using a reflector 52 to modify the phase of the tester signal 51 by signal paths to achieve an equal-phase plane wave 53 at the DUT antenna 20da, thereby producing a QZ with equal-phase plane wave and constant radiation power density along the axial direction 53a, and minimizing path loss after the reflector 52. Also known as a compact antenna test range (CATR), alignment of the reflector system 52 in a mmWave OTA environment can be challenging, and accuracy of and defects in the reflector 52 curvature become more critical. Accordingly, a reflector type CATR test environment 50 may be better suited for a DUT antenna array size that is significantly large relative to the nominal signal wavelength.

Referring to FIG. 7, an improved technique includes use of a lens-type CATR for the mmWave OTA test environment 60 in which a dielectric lens 62 is positioned between the DUT antenna 20da and the tester antenna 20ta. The tester antenna 20ta may be positioned at the focal point of the lens 62. In accordance with principles of geometric optics, the dielectric lens 62 provides phase correction to the tester transmission signal 21ta and creates a quiet zone QZ downstream from the lens 62. Since radiation power density of the signal 63 in the quiet zone QZ remains constant, overall path loss depends primarily on the distance R_{F} between the tester antenna 20ta and the lens 62.

Since power density after the lens 62 remains constant, the factor for path loss improvement as compared to a DFF environment may be expressed as:

$${( \frac{{R}_{min}}{{R}_{F}} )}^{2}$$

For example, a quiet zone QZ with a 10 cm diameter as required for a DUT antenna 20da with Lₘₐₓ=5 cm and a tester antenna beamwidth θ=35°, the focal length may be expressed as:

$${R}_{F} = \frac{5 cm}{tan \frac{θ ( = 3 {5}^{°} )}{2}} = 15.8 cm$$

Accordingly, since the minimum DFF distance Rₘᵢₙ for Lₘₐₓ at 40 GHz is 67 cm, the path loss improvement may be expressed as:

$$10 {log ( \frac{{R}_{min}}{{R}_{F}} )}^{2} or 12.5 dB .$$

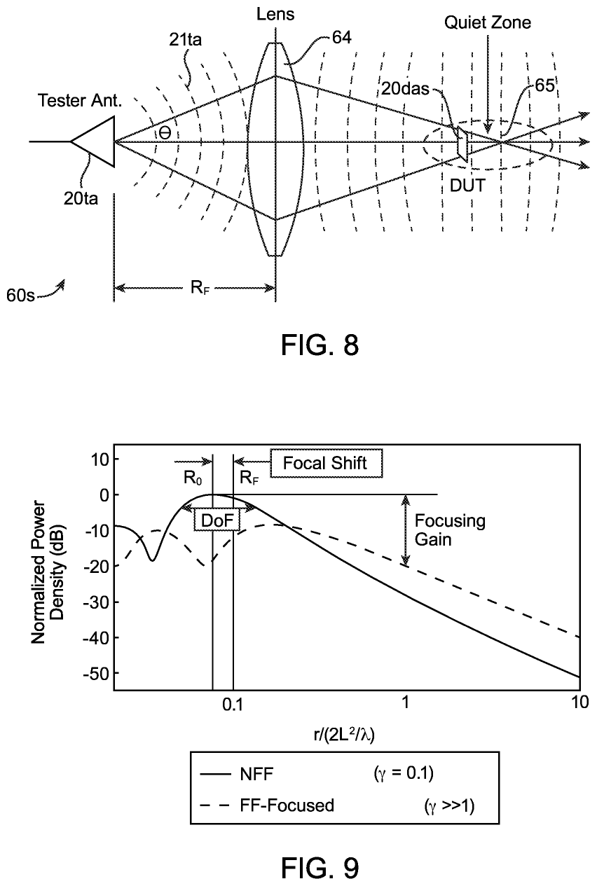

Referring to FIG. 8, for a DUT with a small aperture antenna 20das and low antenna gain, a lens-type CATR can further enhance radiation power density by incorporating a lens 64 having a near-field focus (NFF), thereby providing an equal-phase plane wave 65 near the focal point to form a quiet zone QZ.

Referring to FIG. 9, for example, such a lens-type CATR by NFF environment can achieve close to 20 dB of focusing gain near the focal point, compared to a DFF environment when measured at the FF boundary. This also represents a significant path loss improvement from the non-lens CATR environment (FIG. 6).

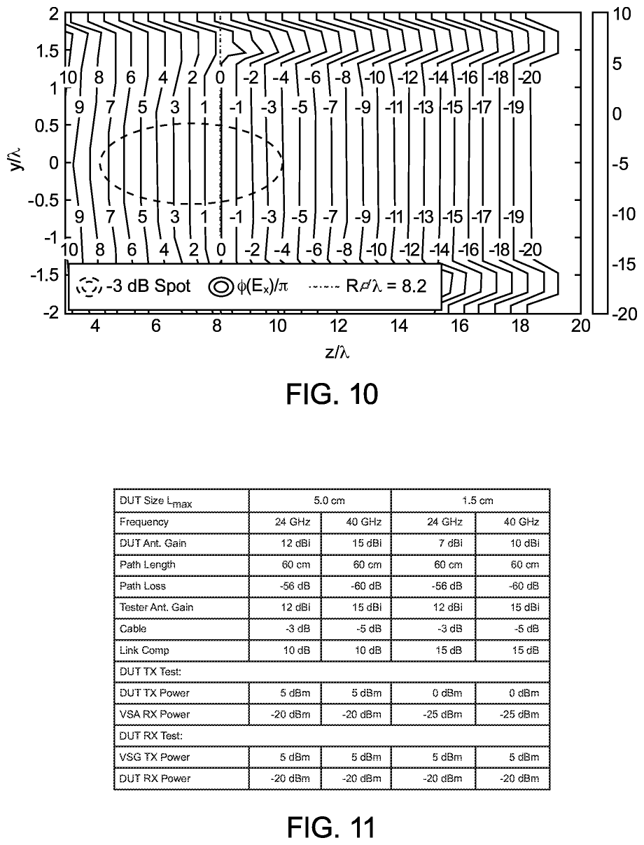

Referring to FIG. 10, field plots of example NFF QZ characteristics demonstrate how more advantageous the limited quiet zone QZ area (in terms of transversal and axial directions) of a NFF environment may be for a smaller size DUT.

Referring to FIG. 11, an example of an OTA link budget for Lₘₐₓ=1.5 and 5.0 cm with 60 cm of path length may be as shown. For example, to provide for reception at the DUT of a −20 dBm signal power level, the path loss compensation should be between 10 to 15 dB.

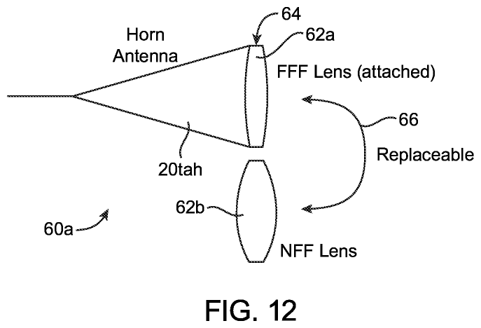

Referring to FIG. 12, as discussed above, NFF and far-field focus (FFF) testing environments offer respective advantageous levels of path loss compensation. One difference between the two techniques is in the lens design, e.g., with one design primarily advantageous for a FFF environment (FIG. 7) while another design may be primarily advantageous for a NFF environment (FIG. 8). Accordingly, both environments may be advantageously accommodated via configurable gains provided by interchangeable lenses. For example, an example testing environment 60a may include a cross-polarized horn antenna 20tah to be driven by the tester, along with multiple lenses 62a, 62b, which may be co-designed for use with the horn antenna 20tah, and a lens attachment interface 64 (e.g., a lens mounting and stabilizing mechanism). Depending on the desired test scenario, an appropriate lens may be selected and positioned in alignment with the antenna 20tah to provide an adequate gain compensation in the range of 10 dB (FFF case) to 20 dB (NFF case). The lens attachment interface 64 may be designed in a manner compatible with the specific antenna configuration to provide mounting stability and consistent alignment with the radiative signal path defined by the antenna 20tah. An automation mechanism 66 for positioning the lenses 62a, 62b may also be implemented (e.g., with a motorized precision lens positioning stage).

Various other modifications and alternatives in the structure and method of operation of this invention will be apparent to those skilled in the art without departing from the scope and the spirit of the invention. Although the invention has been described in connection with specific preferred embodiments, it should be understood that the invention as claimed should not be unduly limited to such specific embodiments. It is intended that the following claims define the scope of the present invention and that structures and methods within the scope of these claims and their equivalents be covered thereby.

1. A system for testing a wireless signal transceiver device under test (DUT) via a wireless signal path, comprising:
a tester antenna configured to emit an electromagnetic tester signal and to receive a focused electromagnetic DUT signal;
a DUT location for disposition of a DUT to receive a focused electromagnetic tester signal and emit an electromagnetic DUT signal; and
an electromagnetic lens disposed between said tester antenna and said DUT location to
focus said electromagnetic tester signal to provide said focused electromagnetic tester signal within a volume that defines a quiet zone region enveloping at least a portion of said DUT location, and
focus said electromagnetic DUT signal to provide said focused electromagnetic DUT signal.

2. The system of claim 1, wherein:
said electromagnetic lens has a focal point associated therewith; and
said tester antenna includes an electromagnetic transducer disposed at said focal point.

3. The system of claim 1, wherein said electromagnetic lens comprises at least one of a far field focus (FFF) lens or a near field focus (NFF) lens.

4. The system of claim 1, wherein:
said electromagnetic lens has a focal point associated therewith; and
said quiet zone region further envelops said focal point.

5. The system of claim 1, wherein said electromagnetic lens comprises a dielectric.

6. The system of claim 1, wherein said electromagnetic lens comprises one of a plurality of interchangeable lens members, and further comprising a lens receptacle adapted to receive and secure each one of said plurality of interchangeable lens members.

7. The system of claim 6, wherein said plurality of interchangeable lens members includes a FFF lens member and a NFF lens member.

8. The system of claim 1, further comprising a shielded enclosure containing said tester antenna, DUT location and electromagnetic lens.

9. The system of claim 1, wherein:
said electromagnetic tester signal comprises a first millimeter wave electromagnetic signal; and
said electromagnetic DUT signal comprises a second millimeter wave electromagnetic signal.

10. A method for testing a wireless signal transceiver device under test (DUT) via a wireless signal path, comprising:
emitting an electromagnetic tester signal from a tester antenna;
focusing, with an electromagnetic lens, said electromagnetic tester signal to provide a focused electromagnetic tester signal within a volume that defines a quiet zone region; and
receiving said focused electromagnetic tester signal with a DUT disposed at least partially in said quiet zone region.

11. The method of claim 10, wherein:
said focusing comprises focusing with an electromagnetic lens having a focal point associated therewith; and
said emitting comprises emitting said electromagnetic tester signal from a tester antenna that includes an electromagnetic transducer disposed at said focal point.

12. The method of claim 10, wherein said electromagnetic lens comprises at least one of a far field focus (FFF) lens or a near field focus (NFF) lens.

13. The method of claim 10, wherein:
said electromagnetic lens has a focal point associated therewith; and
said focal point is disposed in said quiet zone region.

14. The method of claim 10, wherein said focusing comprises focusing with a dielectric.

15. The method of claim 10, wherein said focusing comprises:
focusing with a first one of a plurality of interchangeable lens members during a first interval;
focusing with a second one of said plurality of interchangeable lens members during a second interval; and
interchanging said first and second ones of said plurality of interchangeable lens members during a third interval between said first and second intervals.

16. The method of claim 15, wherein said plurality of interchangeable lens members includes a FFF lens member and a NFF lens member.

17. The method of claim 10, further comprising enclosing said tester antenna, DUT and electromagnetic lens in a shielded enclosure.

18. The method of claim 10, wherein said emitting an electromagnetic tester signal from a tester antenna comprises emitting a millimeter wave electromagnetic signal.

19. The method of claim 10, further comprising:
emitting an electromagnetic DUT signal from said DUT;
focusing, with said electromagnetic lens, said electromagnetic DUT signal to provide a focused electromagnetic DUT signal; and
receiving, with said tester antenna, said focused electromagnetic DUT signal.

20. The method of claim 10, wherein:
said emitting an electromagnetic tester signal from a tester antenna comprises emitting a first millimeter wave electromagnetic signal; and
said emitting an electromagnetic DUT signal from said DUT comprises emitting a second millimeter wave electromagnetic signal.
